(19) United States
(12) Patent Application Publication
(10) Pub. No.: US 2013/0154661 A1
(43) Pub. Date: Jun. 20, 2013

(54) ELECTRONIC COMPONENT INSPECTION APPARATUS

(71) Applicants: Jeong Ho SHIN, Suwon (KR); Hae Man Lee, Suwon (KR); Ik Hyun Shin, Seongnam (KR)

(72) Inventors: Jeong Ho SHIN, Suwon (KR); Hae Man Lee, Suwon (KR); Ik Hyun Shin, Seongnam (KR)

(73) Assignee: Samsung Electro-Mechanics, Co., Ltd.

(21) Appl. No.: 13/564,285

(22) Filed: Aug. 1, 2012

(30) Foreign Application Priority Data
Dec. 19, 2011 (KR) 10-2011-0137132

(51) Int. Cl. G01R 31/02

(52) U.S. Cl. 324/537

(57) ABSTRACT

There is provided an electronic component inspection apparatus. The electronic component inspection apparatus includes a first rotation unit, rotatable based on a first rotating shaft, a plurality of second rotation units rotatably provided in the first rotation unit based on a second rotating shaft, and an inspection unit inspecting characteristics of an electronic component mounted in the second rotation unit.

### CROSS-REFERENCE TO RELATED APPLICATIONS

This application claims the priority of Korean Patent Application No. 10-2011-0137132 filed on Dec. 19, 2011, In the Korean Intellectual Property Office, the disclosure of which is incorporated herein by reference.

### BACKGROUND OF THE INVENTION

1. Field of the Invention

The present invention relates to an electronic component inspection apparatus, and more particularly, to an electronic component inspection apparatus which may rapidly and accurately inspect various characteristics of electronic components.

2. Description of the Related Art

To reduce an electronic component defect rate, and ensure stable performance of the electronic component, it is necessary to inspect the electronic components that are mounted in electronics.

The inspection of the electronic components may be classified into visual inspection and performance inspection. A visual inspection determines whether an electronic component is defective by inspecting the external appearance thereof, while a performance inspection inspects electrical characteristics (for example, capacitance, insulation resistance, and the like) thereof.

In general, a visual inspection of the electronic component may be rapidly and accurately performed through a photographing device.

However, in the performance inspection of an electronic component, a basic time for inspecting the electrical characteristics of the electronic component is required, so that it may be difficult to rapidly and accurately inspect a plurality of electronic components.

In particular, since a significant deviation between a capacitance inspection time of the electronic component and an insulation resistance inspection time thereof is present, it is difficult to simultaneously perform a plurality of performance inspections in a single inspection apparatus or a single inspection line.

### SUMMARY OF THE INVENTION

An aspect of the present invention provides an electronic component inspection apparatus able to rapidly and accurately inspect electrical characteristics of electronic components.

According to an aspect of the present invention, there is provided an electronic component inspection apparatus, including: a first rotation unit, rotatable based on a first rotating shaft; a plurality of second rotation units rotatably provided in the first rotation unit based on a second rotating shaft; and an inspection unit inspecting characteristics of an electronic component mounted in the second rotation unit.

The second rotating shafts may be circularly disposed, based on the first rotating shaft.

The second rotation unit may include a plurality of mounting units on which the electronic components are mounted.

The plurality of mounting units may be circularly disposed, based on the second rotating shaft.

The plurality of mounting units may be formed in a plurality of rows in a radius direction of the second rotation unit.

The inspection unit may include a first inspection unit inspecting a first characteristic of the electronic component, and a second inspection unit inspecting a second characteristic of the electronic component.

The first inspection unit may measure capacitance of the electronic component, and the second inspection unit may measure insulation resistance of the electronic component.

The first inspection unit may be at least one, and the second inspection unit may be at least two.

The first inspection unit and the second inspection unit maybe circularly disposed, based on the first rotating shaft.

The first inspection unit and the second inspection unit may be disposed on the outside of the first rotation unit.

The first inspection unit and the second inspection units may be disposed to correspond to the second rotation unit.

The electronic component inspection apparatus may further include a third rotation unit disposed in the first rotation unit.

The first inspection unit and the second inspection unit may be disposed in the third rotation unit.

The third rotation unit may be relatively rotatable with respect to the first rotation unit.

According to another aspect of the present invention, there is provided an electronic component inspection apparatus, including: a first rotation unit, rotatable based on a first rotating shaft; a plurality of second rotation units rotatably provided in the first rotation unit based on the second rotating shaft, and including a plurality of mounting units on which a plurality of electronic components are mounted; a first inspection unit inspecting first characteristics of the plurality of electronic components mounted in the mounting unit; and a second inspection unit inspecting second characteristics of the plurality of electronic components mounted in the mounting units.

The second inspection unit may be vertically movable along the second rotating shaft.

The first inspection unit may measure capacitance of the electronic component, and the second inspection unit may measure insulation resistance of the electronic component.

The electronic component inspection apparatus may further include a supply unit supplying, to the second rotation unit, the electronic component to be inspected; and a discharge unit discharging the electronic component completed in an inspection from the second rotation unit.

The mounting units may be circularly disposed, based on the second rotating shaft.

The mounting units may be formed in a plurality of rows in a radius direction of the second rotation unit.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 and 2 are configuration views showing an electronic component inspection apparatus according to a first embodiment of the present invention;

FIGS. 3 and 4 are configuration views showing an electronic component inspection apparatus according to a second embodiment of the present invention;

FIG. 5 is a configuration view showing an electronic component inspection apparatus according to a third embodiment of the present invention;

FIG. 6 is a configuration view showing an electronic component inspection apparatus according to a fourth embodiment of the present invention;

FIG. 7 is a configuration view showing an electronic component inspection apparatus according to a fifth embodiment of the present invention;

FIG. 8 is a side view showing the electronic component inspection apparatus shown in FIG. 7; and

FIG. 9 is a modified example of the electronic component inspection apparatus shown in FIG. 7.

### DETAILED DESCRIPTION OF THE EMBODIMENTS

Hereinafter, embodiments of the present invention will be described in detail with reference to the accompanying drawings.

In describing the present invention below, terms indicating components of the present invention are named in consideration of functions of each component. Therefore, the terms should not be understood to limit technical component elements of the present invention.

In order to perform performance inspection of an electronic component, at least two electrical characteristics may need to be inspected. For example, for the purpose of performance inspection of a multilayer ceramic capacitor (hereinafter, referred to as “MLCC”), capacity inspection and insulation resistance inspection may be performed.

However, the capacity inspection of the MLCC may be performed within a relatively short period of time, however, the insulation resistance inspection of the MLCC may require a relatively long period of time.

Therefore, when a plurality of MLCCs are inspected in a single inspection line, a performance inspection speed of the MLCC may be delayed by a time required for the insulation resistance inspection of the MLCC.

Meanwhile, a plurality of insulation resistance inspection apparatuses may be disposed to improve the performance inspection speed of the MLCCs, but, in this case, it may be difficult to continuously supply the MLCCs while the insulation resistance inspection of the MLCCs are performed.

In order to solve the above described defect, an electronic component inspection apparatus able to continuously inspect a plurality of electronic components (particularly, MLCCs) according to an embodiment of the present invention may be provided.

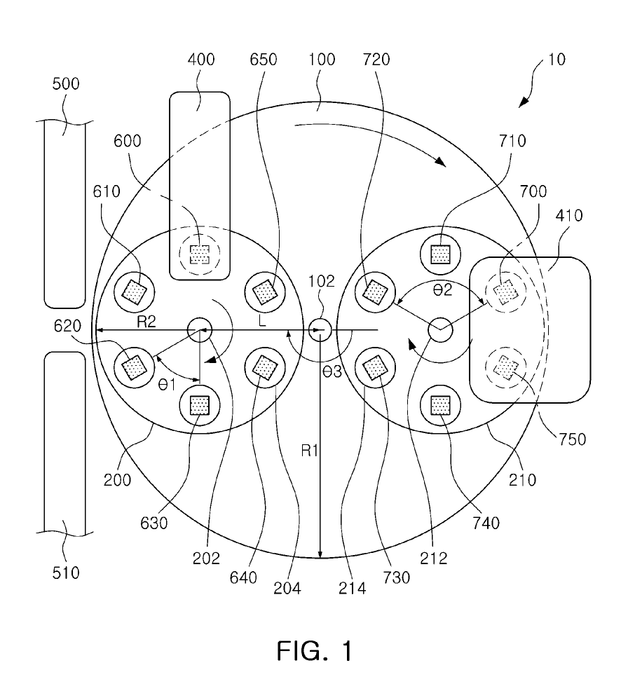

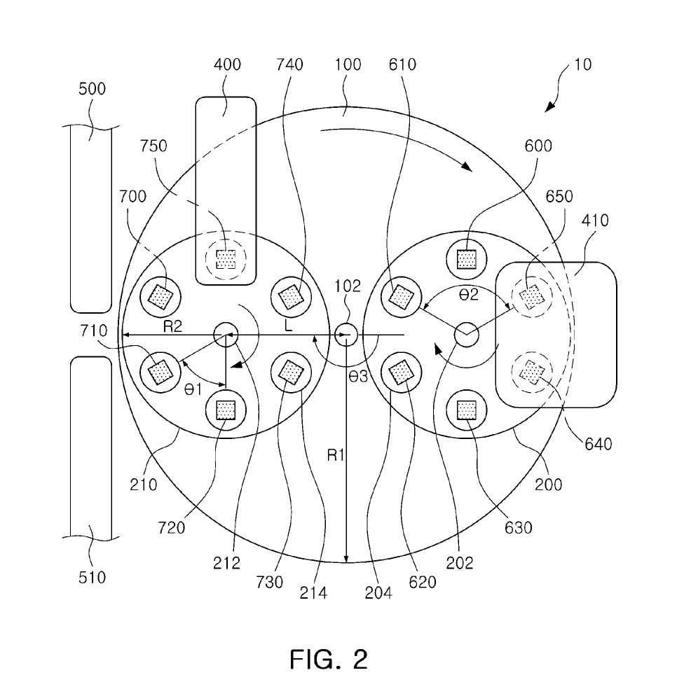

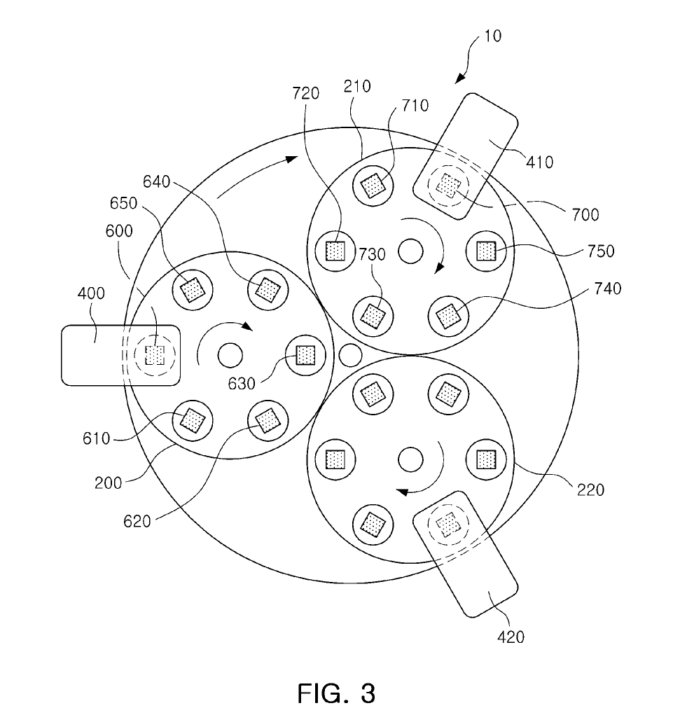

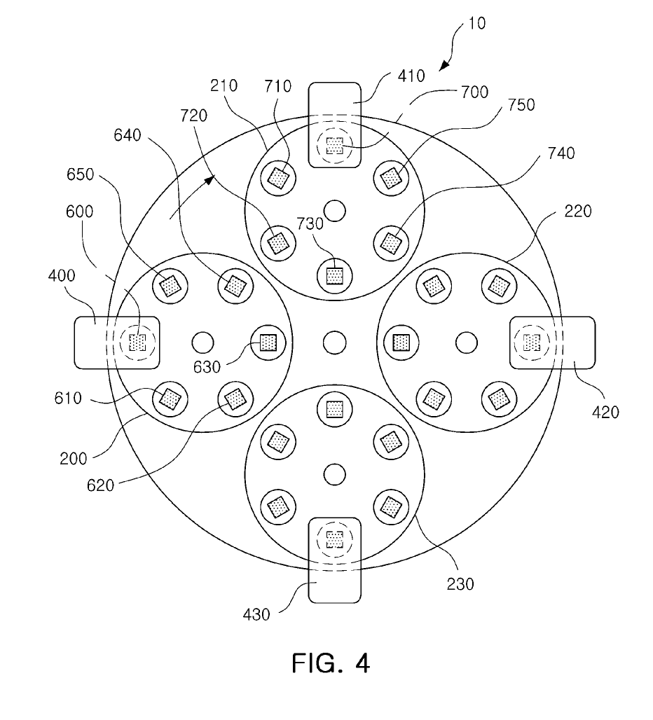

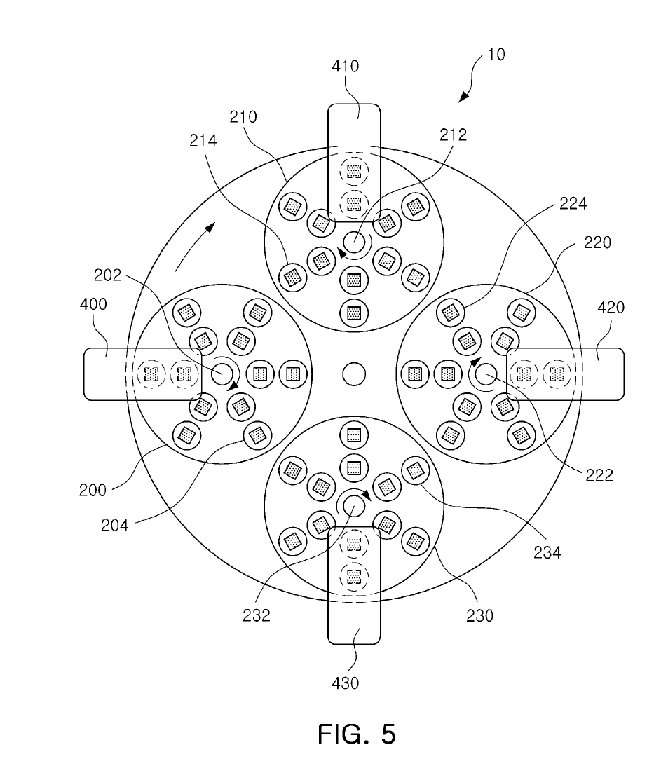

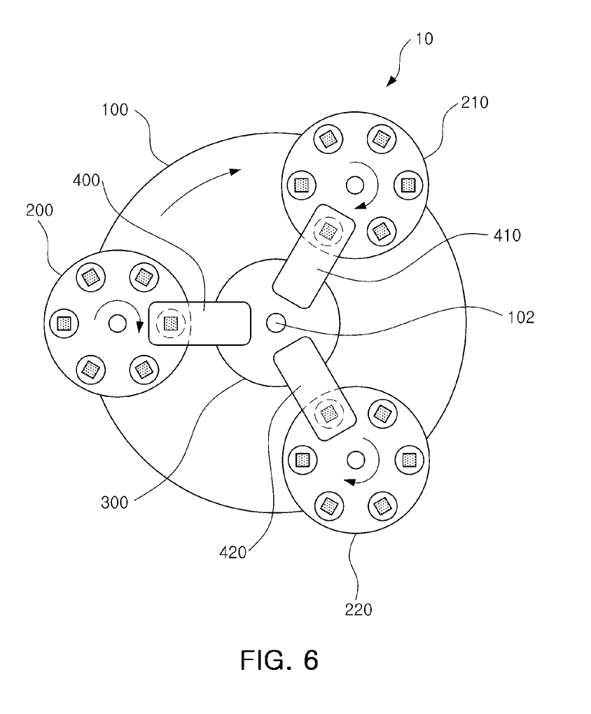

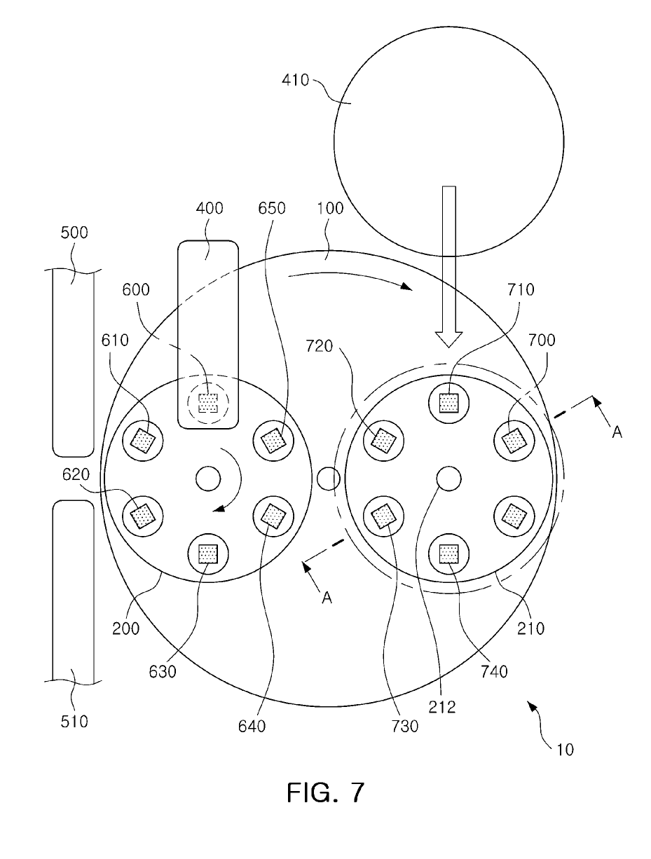

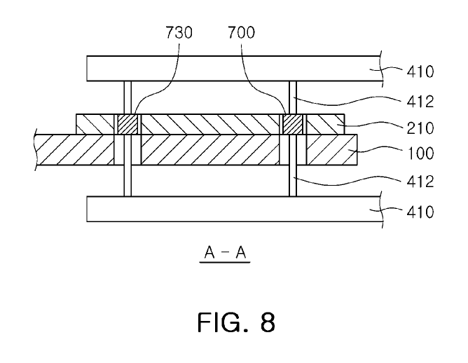

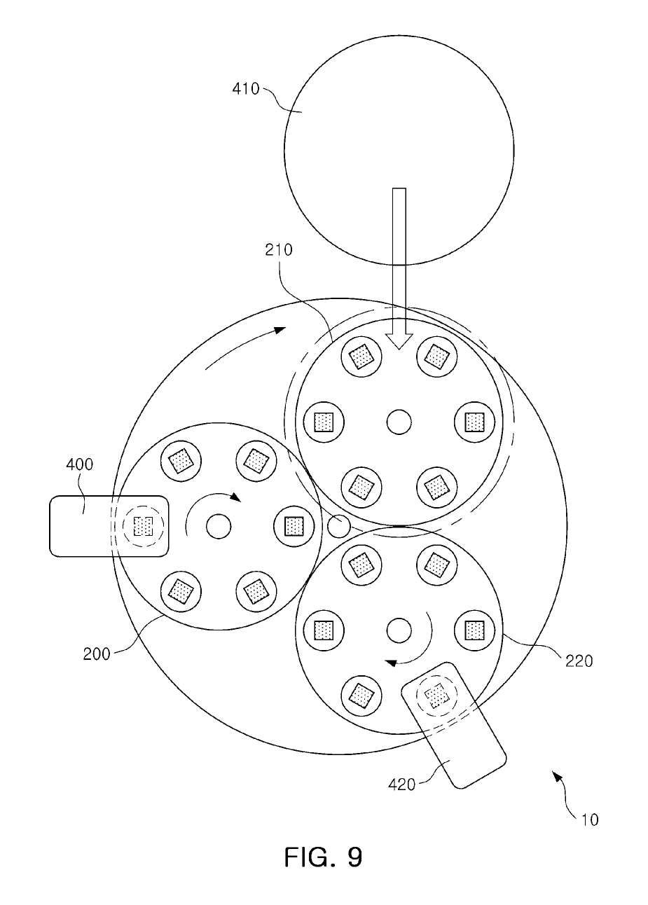

FIGS. 1 and 2 are configuration views showing an electronic component inspection apparatus according to a first embodiment of the present invention, FIGS. 3 and 4 are configuration views showing an electronic component inspection apparatus according to a second embodiment of the present invention, FIG. 5 is a configuration view showing an electronic component inspection apparatus according to a third embodiment of the present invention, FIG. 6 is a configuration view showing an electronic component inspection apparatus according to a fourth embodiment of the present invention, FIG. 7 is a configuration view showing an electronic component inspection apparatus according to a fifth embodiment of the present invention, FIG. 8 is a side view showing the electronic component inspection apparatus shown in FIG. 7, and FIG. 9 is a modified example of the electronic component inspection apparatus shown in FIG. 7.

An electronic component inspection apparatus according to a first embodiment of the present invention will be described in detail with reference to FIGS. 1 and 2.

The electronic component inspection apparatus 10 according to the first embodiment of the present invention may include a first rotation unit 100, second rotation units 200 and 210, and inspection units 400 and 410. Furthermore, the electronic component inspection apparatus 10 may further include an electronic component supply unit 500 and an electronic component discharge unit 510.

In addition, the electronic component inspection apparatus 10 may further include a first transport head (not shown) that transports an electronic component of the electronic component supply unit 500 to the second rotation unit 200, and a second transport head (not shown) that transports an electronic component of the second rotation unit 200 to the electronic component discharge unit 510. Here, the first transport head and the second transport head may be provided in a single device, or may be integrally formed as one device.

The first rotation unit 100 may have a first rotating shaft 102, and may be formed in a disk shape having a first radius R1, based on the first rotating shaft 102.

The first rotation unit 100 may rotate based on the first rotating shaft 102. Here, the rotation of the first rotation unit 100 maybe intermittently performed by a control unit (not shown). For example, the first rotation unit 100 shown in FIG. 1 may be rotated at every 180 degrees for each prescribed time. That is, the first rotation unit 100 may be rotated at every 180 degrees by a first operation signal of the control unit.

However, a rotation angle of the first rotation unit 100 may be different depending on the number of the second rotation units 200 and 210 formed in the first rotation unit 100. For example, when three second rotation units are formed in the first rotation unit 100, a rotation angle of the first rotation unit 100 due to a single operation thereof may be 120 degrees. In addition, when four second rotation units are formed in the first rotation unit 100, a rotation angle of the first rotation unit 100 due to a single operation thereof may be 90 degrees.

The second rotation units 200 and 210 may respectively have second rotating shafts 202 and 212, and may be formed in a disk shape having a second radius R2, based on the second rotating shafts 202 and 212, respectively.

The second rotation units 200 and 210 may be coupled with the first rotation unit 100. Specifically, the second rotation units 200 and 210 may be coupled with the first rotation unit 100 through the second rotating shafts 202 and 212, and may be rotated, based on the second rotating shafts 202 and 212, on the first rotation unit 100. Here, a distance L between each of the second rotating shafts 202 and 212 and the first rotating shaft 102 may be smaller than the first radius R1.

The second rotation units 200 and 210 may respectively include mounting units 204 and 214. The mounting units 204 and 214 may be a space in which electronic components are mounted. For example, the mounting units 204 and 214 may be a concave space formed in the second rotation units 200 and 210. Alternatively, each of the mounting units 204 and 214 may be a separate member able to be coupled with the electronic components.

The mounting units 204 and 214 formed as above may be circularly disposed on the first rotation unit 100, based on each of the second rotating shafts 202 and 212. For example, the plurality of respective mounting units 204 and 214 may be arranged at predetermined intervals therebetween, based on the second rotating shafts 202 and 212 as shown in FIG. 1. Meanwhile, in FIG. 1, six mounting units including the mounting units 204 and 214 are formed in the second rotation units 200 and 210, however, the number of the mounting units including the mounting units 204 and 214 may be reduced or increased depending on a type of the electronic component.

The second rotation units 200 and 210 may be respectively rotated based on the second rotating shafts 202 and 212. Here, the rotation of the second rotation units 200 and 210 may be intermittently performed by the control unit (not shown). For example, the second rotation units 200 and 210 shown in FIG. 1 may be rotated at every 60 degrees for each prescribed time. That is, the second rotation units 200 and 210 may be rotated at every 60 degrees by a second operation signal of the control unit.

However, a rotation angle of each of the second rotation units 200 and 210 may be different depending on the number of the mounting units including the mounting units 204 and 214 formed in the second rotation units 200 and 210. For example, when four mounting units are formed in each of the second rotation units 200 and 210, a rotation angle of each of the second rotation units 200 and 210 due to a single operation may be 90 degrees. In addition, when eight mounting units are formed in each of the second rotation units 200 and 210, a rotation angle of each of the second rotation units 200 and 210 due to a single operation thereof may be 45 degrees.

The inspection units 400 and 410 may be a device which inspects electrical characteristics of electronic components. For example, the first inspection unit 400 may be a device that measures a first characteristic (capacitance) of the electronic component, and the second inspection unit 410 may be a device that measures a second characteristic (insulation resistance) of the electronic component.

The first inspection unit 400 may be a device that inspects a single electronic component at a time, and the second inspection unit 410 may be a device that inspects at least two electronic components at a time. Alternatively, a single first inspection unit 400 may be provided, while a plurality of second inspection units 410 may be provided so as to inspect a plurality of electronic components at a time.

Here, the number of the second inspection units 410 or the number of electronic components which are inspected by the second inspection unit 410 at a time may be increased in proportion to a proportional value of the inspection time between the first characteristic and the second characteristic. For example, when a first characteristic inspection time is 10 seconds, and a second characteristic inspection time is 20 seconds, the number of second inspection units 410 may be twice the number of first inspection units 400. When the first characteristic inspection time is 10 seconds and the second characteristic inspection time is 30 seconds, the number of second inspection units 410 may be three times the number of first inspection units 400.

The above described configuration may be useful for a case in which an insulation resistance inspection time of the electronic component is longer than a capacitance inspection time of the electronic component. However, in a case in which inspection characteristics through the first inspection unit 400 require a longer time than that of inspection characteristics through the second inspection unit 410, it may be vice versa.

The inspection units 400 and 410 may be disposed in an edge of the first rotation unit 100. Specifically, the first inspection unit 400 and the second inspection unit 410 may be disposed to respectively inspect electronic components of the second rotation units 200 and 210 which are different from each other.

For example, the first inspection unit 400 may be disposed to inspect an electronic component of the second rotation unit 200, and the second inspection unit 410 may be disposed to inspect electronic components of the second rotation unit 210. However, this is a disposition state based on FIG. 1. Accordingly, when the first rotation unit 100 is rotated by 180 degrees, an inspection target of the inspection units 400 and 410 may be changed.

The electronic component supply unit 500 may be a device that continuously or discontinuously supplies electronic components. For example, the electronic component supply unit 500 may be a conveyer.

The electronic component supply unit 500 may supply electronic components to the second rotation units 200 and 210. For example, the electronic component supply unit 500 may be selectively connected with the second rotation units 200 and 210 to supply electronic components. Alternatively, the electronic component supply unit 500 may supply the electronic components to the second rotation units 200 and 210 through the first transport head.

The electronic component discharge unit 510 may be a device that continuously or discontinuously discharges electronic components. For example, the electronic component discharge unit 510 may be a conveyer.

The electronic component discharge unit 510 may discharge electronic components of the second rotation units 200 and 210 to the outside. For example, the electronic component discharge unit 510 may be selectively connected with the second rotation units 200 and 210 to discharge the electronic components to the outside. Alternatively, the electronic component discharge unit 510 may discharge electronic components from the second rotation units 200 and 210 to the outside through the second transport head.

Hereinafter, an inspection process using the electronic component inspection apparatus configured as above will be described.

An inspection process of the electronic component inspection apparatus according to an embodiment of the present invention may include an electronic component supply, a first inspection, a position change, a discharge and second inspection.

### Electronic Component Supply

The electronic component supply may be performed to supply an electronic component. That is, in this operation, electronic components 600, 610, 620, 630, 640, and 650 may be supplied to the second rotation unit 200 through the electronic component supply unit 500.

The electronic components may be continuously or discontinuously supplied to the second rotation unit 200 by the electronic component supply unit 500. Here, the electronic components of the electronic component supply unit 500 may be mounted in the mounting unit 204 of the second rotation unit 200 by a separate transport head.

Meanwhile, in this operation, the second rotation unit 200 maybe rotated at a constant speed. For example, the second rotation unit 200 may be rotated at a first time interval so that new mounting units 204 are adjacent to the electronic component supply unit 500. Here, the first time interval may be a time required for mounting electronic components of the electronic component supply unit 500 in the mounting units 204.

However, when the first transport head automatically transports the electronic components of the electronic component supply unit 500 to each of the mounting units 204, the second rotation unit 200 may not be rotated in this operation.

### First Inspection

The first inspection may be performed to inspect a single characteristic of an electronic component. That is, in this operation, the inspection units 400 and 410 may inspect a first characteristic and a second characteristic of electronic components.

Specifically, when the electronic components are mounted in all of the mounting units 204 of the second rotation unit 200, the first inspection unit 400 may inspect the electronic components 600, 610, 620, 630, 640 and 650 of the mounting units 204. For example, the first inspection unit 400 may inspect a single electronic component at a time, and measure the first characteristic of the electronic component (for example, a capacitance).

The first inspection unit 400 may transmit a measured first inspection value to the control unit. Alternatively, the first inspection unit 400 may determine, based on the first inspection value, whether a corresponding electronic component is defective. Meanwhile, an electronic component determined as being defective by the first inspection unit 400 or the control unit may be removed by a separate transport head in this operation or in a later operation.

The second rotation unit 200 may be rotated at a second time interval. For example, when a first characteristic inspection of the electronic component 600 through the first inspection unit 400 is completed, the second rotation unit 200 may be rotated by a first angle (θ1).

Here, the second time interval may be a time required for inspecting a first characteristic of an electronic component. In addition, the first angle (θ1) may be an angle formed by the two adjacent mounting units 204 and the second rotating shaft 202. For example, in FIG. 1, the first angle (θ1) may be 60 degrees. However, since the first angle is limited to the present embodiment, the first angle (θ1) may be different depending on the number of mounting units 204 formed in the second rotation unit 200.

The first inspection unit 400 may require the first inspection time so as to inspect the first characteristics of the electronic components 600, 610, 620, 630, 640, and 650. Here, the first inspection time T1 may be represented by the following Equation 1.

T1=(E1+Tr2)×Pn [Equation 1]

Here, T1 denotes a time required for inspecting first characteristics of all of the electronic components mounted in the second rotation unit, E1 denotes a time required for inspecting a first characteristic of an electronic component, Tr2 denotes a time required when the second rotation unit is rotated by a first angle, and Pn denotes a total number of electronic components mounted in the second rotation unit.

Meanwhile, the inspection of electronic components through the first inspection unit 400 may be performed simultaneously with supplying the electronic components.

In this operation, the inspection of the electronic component through the second inspection unit 410 may be simultaneously performed. That is, when electronic components are mounted in the second rotation unit 210, the second inspection unit 410 may inspect second characteristics of corresponding electronic components 700, 710, 720, 730, 740, and 750.

For example, the second inspection unit 410 may inspect at least two electronic components at a time, and measure a second characteristic of the electronic component (for example, an insulation resistance).

The second inspection unit 410 may transmit a measured second inspection value to the control unit. Alternatively, the second inspection unit 410 may determine, based on the second inspection value, whether a corresponding electronic component is defective. Meanwhile, the electronic component determined as being defective by the second inspection unit 410 or the control unit may be removed by a separate transport head in this operation or in a later operation.

The second rotation unit 210 may be rotated at a third time interval. For example, when a second characteristic inspection of the electronic components 700 and 750 through the second inspection unit 410 is completed, the second rotation unit 210 may be rotated by a second angle (θ2).

Here, the third time interval may be a time required for inspecting a second characteristic of an electronic component. In addition, the second angle (θ2) may be an angle formed by a currently inspected electronic component, a subsequently inspected electronic component, and the second rotating shaft 212. Specifically, the second angle (θ2) may be a value obtained by multiplying the first angle (θ1) by the number of electronic components inspected through the second inspection unit 410. For example, in FIG. 1, the second angle (θ2) may be 120 degrees. However, the second angle may be different depending on the number of mounting units 214 formed in the second rotation unit 210, similar to the first angle.

The second inspection unit 410 may require a second inspection time so as to inspect second characteristics of the electronic components 700, 710, 720, 730, 740, and 750. Here, the second inspection time T2 may be represented by the following Equation 2.

T2=(E2+Tr2)×Pn/E2n [Equation 2]

Here, T2 denotes a time required for inspecting second characteristics of all of the electronic components mounted in the second rotation unit, E2 denotes a time required for inspecting a second characteristic of an electronic component, Tr2 denotes a time required when the second rotation unit is rotated by the second angle, Pn denotes a total number of electronic components mounted in the second rotation unit, and E2n denotes the number of electronic components able to be inspected by the second inspection unit 410 at a time.

For reference, the electronic components 700, 710, 720, 730, 740, and 750 of the second rotation unit 210 may be components completed in the first characteristic inspection through the first inspection unit 400.

In this operation described as above, the first characteristic and the second characteristic of the electronic component may be simultaneously inspected, so that electrical characteristics of the electronic component may be rapidly inspected.

### Position Change

The position change may be performed to change a position of the second rotation unit with respect to the inspection unit.

That is, in this operation, a relative position of the second rotation units 200 and 210 with respect to the inspection units 400 and 410 may be changed as shown in FIG. 2 by rotating the first rotation unit 100.

When the first inspection unit 400 completes a first characteristic inspection for electronic components of the second rotation unit 200, and the second inspection unit 410 completes a second characteristic inspection for electronic components of the second rotation unit 210, the first rotation unit 100 may be rotated by a third angle (θ3). Here, the third angle (θ3) may be an angle formed by the second rotation units 200 and 210 and the first rotating shaft 102. For example, in FIG. 1, the third angle (θ3) may be 180 degrees.

When the first rotation unit 100 is rotated by the third angle (θ3), a relative position of the second rotation units 200 and 210 with respect to the inspection units 400 and 410 may be changed, so that characteristics of new electronic components may be inspected through the inspection units 400 and 410 (see, FIG. 2).

### Discharging and Second Inspection

The discharging and second inspection may be performed to discharge a part of electronic components and inspect other characteristics of other electronic components.

That is, in this operation, the second inspection unit 410 may inspect electronic components of the second rotation unit 210, and a second transport head (not shown) may discharge electronic components of the second rotation unit 210.

Since the electronic components 600, 610, 620, 630, 640, and 650 of the second rotation unit 200 are components only completed in the first characteristic inspection through the first inspection unit 400, a second characteristic inspection thereof may be subsequently performed through the second inspection unit 410.

Unlike this, the electronic components 700, 710, 720, 730, 740 and 750 of the second rotation unit 210 may be components all completed in the characteristic inspection through the first inspection unit 400 and the second inspection unit 410, thereby being discharged in this operation.

The electronic components completed in the inspection may be transported to other processes through the electronic component discharge unit 510. In addition, components which are determined as being defective from among the inspected electronic components may be removed by a separate transport unit.

Meanwhile, when the electronic components 700, 710, 720, 730, 740 and 750 are discharged from the mounting unit 214 of the second rotation unit 210, new electronic components may be mounted in the empty mounting unit 214. That is, discharge of the electronic components from the mounting unit 214 and supply of the electronic components to the mounting unit 214 may be simultaneously performed.

Since the electronic component inspection apparatus performing the operation described as above simultaneously performs the first characteristic and second characteristic inspections of the electronic component, an inspection time of the electronic components may be significantly reduced.

That is, in the present embodiment, the first characteristic inspection of the electronic components and the second characteristic inspection thereof are respectively performed by the separate rotation units 200 and 210, so that a waiting time generated when inspecting different electrical characteristics in a single line may be significantly reduced.

For example, when performing the first characteristic inspection of the electronic component and the second characteristic inspection thereof in a single line, a waiting time (30 seconds−20 seconds=10 seconds) may be generated by a difference between a time required for the first characteristic inspection (for example, 10 seconds) and a time required for the second characteristic inspection (for example, 20 seconds).

On the other hand, in the present embodiment, a time required for inspecting first characteristics of six electronic components through the second rotation unit 200 is 60 seconds (6×10=60), and a time required for inspecting second characteristics of the six electronic components through another second rotation unit 210 is 60 seconds (6/2×20=60) (see, Equation 2), so that the first and second characteristics of the six electronic components may be substantially inspected in a continuous manner without a waiting time.

Hereinafter, other embodiments of the present invention will be described with reference to FIGS. 3 through 9. For reference, in the following embodiments, the same components as those in the first embodiment may refer to the same reference numerals, and a detailed description thereof will be omitted.

An electronic component inspection apparatus according to a second embodiment of the present invention will be described with reference to FIGS. 3 and 4.

The electronic component inspection apparatus 10 according to the second embodiment may be different from the electronic component inspection apparatus 10 according to the first embodiment in terms of the number of second rotation units and the number of inspection units.

The electronic component inspection apparatus 10 shown in FIG. 3 may include three second rotation units 200, 210 and 220, and three inspection units 400, 410 and 420, and the electronic component inspection apparatus 10 shown in FIG. 4 may include four second rotation units 200, 210, 220, 230, and four inspection units 400, 410, 420, and 430.

The second rotation units 200, 210, 220 and 230 may include a plurality of electronic components. Each of the second rotation units 200, 210, 220 and 230 may be rotated at a second time interval or a third time interval. Alternatively, each of the second rotation units 200, 210, 220 and 230 may be rotated at the same time interval, and rotated at different time intervals.

The inspection units 400, 410, 420 and 430 may inspect a first characteristic or a second characteristic of the electronic component, or characteristics other than these characteristics. For example, the first inspection unit 400 may inspect a first characteristic of an electronic component (for example, a capacitance), and the remaining inspection units 410, 420 and 430 may inspect a second characteristic of the electronic component (for example, an insulation resistance). Alternatively, the first inspection unit 400 may inspect the first characteristic of the electronic component, the second and third inspection units 410 and 420 may inspect the second characteristic of the electronic component, and the fourth inspection unit 430 may inspect a third characteristic of the electronic component.

In the electronic component inspection apparatus 10 configured as above, a plurality of second rotation units 200, 210, 220 and 230 may be formed in the first rotation unit 100, thereby relatively more rapidly inspecting a plurality of electronic components.

In addition, the electronic component inspection apparatus 10 configured as above includes a plurality of inspection units, thereby simultaneously inspecting various characteristics of the electronic components.

Hereinafter, an electronic component inspection apparatus according to a third embodiment of the present invention will be described with reference to FIG. 5.

The electronic component inspection apparatus 10 according to the third embodiment may be different from the electronic component inspection apparatuses 10 according to the above described embodiments in terms of a shape of the mounting unit.

That is, as shown in FIG. 5, the second rotation units 200, 210, 220 and 230 may include mounting units 204, 214, 224 and 234 which are formed in a plurality of rows. Specifically, the mounting units 204, 214, 224, and 234 may be circularly disposed, based on the second rotating shafts 202, 212, 222, and 232 as a center, and at the same time, may be arranged in a plurality of rows along a radius direction of each of the second rotation units 200, 210, 220, and 230.

In the electronic component inspection apparatus 10 configured as above, a relatively more number of electronic components may be mounted in the second rotation units 200, 210, 220 and 230, thereby relatively more improving an inspection speed of the electronic component.

Hereinafter, an electronic component inspection apparatus according to a fourth embodiment of the present invention will be described with reference to FIG. 6.

The electronic component inspection apparatus 10 according to the fourth embodiment may be different from the electronic component inspection apparatuses 10 according to the above described embodiments in terms of a disposition structure of the inspection units 400, 410 and 420.

The electronic component inspection apparatus 10 may further include a third rotation unit 300 as shown in FIG. 6.

The third rotation unit 300 may be coupled to the first rotation unit 100. Specifically, the third rotation unit 300 may be coupled with the first rotating shaft 102 of the first rotation unit 100.

The third rotation unit 300 may relatively rotate with respect to the first rotation unit 100. Specifically, the third rotation unit 300 may not be rotated when the first rotation unit 100 is rotated, and may maintain a current position as it is. That is, the third rotation unit 300 may not be rotated together with the first rotation unit 100.

The inspection units 400, 410 and 420 may be formed in the third rotation unit 300. The inspection units 400, 410 and 420 may be disposed in the third rotation unit 300 so as to respectively correspond to the second rotation units 200, 210 and 220 of the first rotation unit 100.

In the electronic component inspection apparatus 10 configured as above, the inspection units 400, 410 and 420 maybe disposed on the first rotation unit 100, thereby reducing the overall size of the electronic component inspection apparatus 10.

Hereinafter, an electronic component inspection apparatus according to a fifth embodiment of the present invention will be described with reference to FIGS. 7 through 9.

The electronic component inspection apparatus 10 according to the fifth embodiment may be different from the electronic component inspection apparatuses 10 according to the above described embodiments in terms of the second inspection unit 410.

That is, in the electronic component inspection apparatus 10, the second inspection unit 410 may have a structure for simultaneously inspecting characteristics of the electronic components mounted in the second rotation unit 210. In addition, the second inspection unit 410 may be a device able to inspect a plurality of characteristics.

The second inspection unit 410 may be moved in a horizontal direction as shown in FIG. 7, or moved in a vertical direction (the direction based on FIG. 8) based on the second rotation unit 210.

In addition, the second inspection unit 410 may include a plurality of terminals 412 so as to be connected with a plurality of electronic components as shown in FIG. 8. The plurality of terminals 412 may be connected with the electronic components of the second rotation unit 210 according to a vertical movement of the second inspection unit 410.

The second inspection unit 410 having the above described structure may be connected with all of the electronic components of the second rotation unit 210, thereby simultaneously inspecting electrical characteristics of the electronic components. Accordingly, in the present embodiment, the second rotation unit 210 may not be rotated unlike the rotation unit of reference numeral 200.

In the electronic component inspection apparatus 10 configured as above, the second inspection unit 410 may inspect the electronic components of the second rotation unit 210 at a time while the first inspection unit 400 separately inspects the electronic components of the second rotation unit 200, thereby sufficiently ensuring an inspection time of the second inspection unit 410.

Accordingly, the present embodiment may be useful when characteristics of the electronic components requiring a significantly long inspection time are inspected through the second inspection unit 410.

Meanwhile, the electronic component inspection apparatus 10 according to the fifth embodiment may further include the second rotation unit 220 and the inspection unit 420 as shown in FIG. 9.

As set forth above, according to the embodiments of the present invention, the first characteristic of an electronic component (for example, a capacitance) and the second characteristic of the electronic component (for example, an insulation resistance) may be inspected in a single device, thereby significantly reducing time required for the performance inspection of the electronic component.

While the present invention has been shown and described in connection with the embodiments, it will be apparent to those skilled in the art that modifications and variations can be made without departing from the spirit and scope of the invention as defined by the appended claims.

What is claimed is:

1. An electronic component inspection apparatus, comprising:
a first rotation unit, rotatable based on a first rotating shaft;
a plurality of second rotation units rotatably provided in the first rotation unit based on a second rotating shaft; and
an inspection unit inspecting characteristics of an electronic component mounted in the second rotation unit.

2. The electronic component inspection apparatus of claim 1, wherein the second rotating shafts are circularly disposed, based on the first rotating shaft.

3. The electronic component inspection apparatus of claim 1, wherein the second rotation unit includes a plurality of mounting units on which the electronic components are mounted.

4. The electronic component inspection apparatus of claim 3, wherein the plurality of mounting units are circularly disposed, based on the second rotating shaft.

5. The electronic component inspection apparatus of claim 4, wherein the plurality of mounting units are formed in a plurality of rows in a radius direction of the second rotation unit.

6. The electronic component inspection apparatus of claim 1, wherein the inspection unit includes a first inspection unit inspecting a first characteristic of the electronic component, and a second inspection unit inspecting a second characteristic of the electronic component.

7. The electronic component inspection apparatus of claim 6, wherein the first inspection unit measures capacitance of the electronic component, and the second inspection unit measures insulation resistance of the electronic component.

8. The electronic component inspection apparatus of claim 6, wherein the first inspection unit is at least one, and the second inspection unit is at least two.

9. The electronic component inspection apparatus of claim 6, wherein the first inspection unit and the second inspection unit are circularly disposed, based on the first rotating shaft.

10. The electronic component inspection apparatus of claim 9, wherein the first inspection unit and the second inspection unit are disposed on the outside of the first rotation unit.

11. The electronic component inspection apparatus of claim 10, wherein the first inspection unit and the second inspection units are disposed to correspond to the second rotation unit.

12. The electronic component inspection apparatus of claim 9, further comprising a third rotation unit disposed in the first rotation unit.

13. The electronic component inspection apparatus of claim 12, wherein the first inspection unit and the second inspection unit are disposed in the third rotation unit.

14. The electronic component inspection apparatus of claim 13, wherein the third rotation unit is relatively rotatable with respect to the first rotation unit.

15. An electronic component inspection apparatus, comprising:
a first rotation unit, rotatable based on a first rotating shaft;
a plurality of second rotation units rotatably provided in the first rotation unit based on the second rotating shaft, and including a plurality of mounting units on which a plurality of electronic components are mounted;
a first inspection unit inspecting first characteristics of the plurality of electronic components mounted in the mounting units; and
a second inspection unit inspecting second characteristics of the plurality of electronic components mounted in the mounting units.

16. The electronic component inspection apparatus of claim 15, wherein the second inspection unit is vertically movable along the second rotating shaft.

17. The electronic component inspection apparatus of claim 15, wherein the first inspection unit measures capacitance of the electronic component, and the second inspection unit measures insulation resistance of the electronic component.

18. The electronic component inspection apparatus of claim 15, further comprising:
a supply unit supplying, to the second rotation unit, the electronic component to be inspected; and
a discharge unit discharging the electronic component completed in an inspection from the second rotation unit.

19. The electronic component inspection apparatus of claim 15, wherein the mounting units are circularly disposed, based on the second rotating shaft.

20. The electronic component inspection apparatus of claim 19, wherein the mounting units are formed in a plurality of rows in a radius direction of the second rotation unit.
